(19) United States
(12) Patent Application Publication
(10) Pub. No.: US 2013/0052760 A1
(43) Pub. Date: Feb. 28, 2013

(54) METHOD OF INSPECTING AND MANUFACTURING A STACK CHIP PACKAGE

(71) Applicants: Sung-Dong CHO, Hwaseong-si (KR); Yeong-Lyeol PARK, Yongin-si (KR); Min-Seung YOON, Seoul (KR)

(72) Inventors: Sung-Dong CHO, Hwaseong-si (KR); Yeong-Lyeol PARK, Yongin-si (KR); Min-Seung YOON, Seoul (KR)

(73) Assignee: SAMSUNG ELECTRONICS CO., LTD., Suwon-si (KR)

(21) Appl. No.: 13/545,385

(22) Filed: Jul. 10, 2012

(30) Foreign Application Priority Data
Aug. 26, 2011 (KR) 10-2011-0085774

(51) Int. Cl. H01L 21/66

(52) U.S. Cl. 438/15; 257/E21.521

(57) ABSTRACT

In an exemplary method of inspecting a stack chip package, a first chip is prepared. The first chip includes a through-silicon via, first pad electrodes connected to the through-silicon via and probe pad electrodes connected to the through-silicon via. A testing chip is prepared. The testing chip includes second pad electrodes that are arranged to correspond with the first pad electrodes. The testing chip is temporarily adhered to the first chip such that the second pad electrodes are electrically connected to the first pad electrode respectively, to form a stack structure wherein the probe pad electrodes are exposed to for testing. An electrical signal is applied to the exposed probe pad electrodes to test the through-silicon via included in the first chip.

### PRIORITY STATEMENT

This application claims priority under 35 U.S.C. §119 to Korean Patent Application No. 2011-85774, filed on Aug. 26, 2011 in the Korean Intellectual Property Office (KIPO), the entire contents of which are herein incorporated by reference.

### BACKGROUND

1. Field

Exemplary embodiments in accordance with principles of inventive concepts relate to a method of inspecting a stack chip package and .a method of manufacturing the stack chip package. More particularly, exemplary embodiments in accordance with principles of inventive concepts relate to a method of inspecting a stack chip package, which may include though silicon via (TSV), and a method of manufacturing the stack chip package.

2. Description of the Related Art

Three-dimensional integration, where, for example, wafers may be stacked three-dimensionally, may be employed to increase levels of integrated circuit integration. A technique called through silicon via (TSV) may be used to electrically connect and stack a plurality of integrated circuit chips to form a stack-chip package. A stack-chip package may, constitute, for example, a system in package. It would be highly desirable to inspect a stack-chip package in a way that ensures operability of a completed stack and, at the same time, maximizes the use of stack-chip component packages.

### SUMMARY

Exemplary embodiments in accordance with principles of inventive concepts provide a method of inspecting a stack chip package.

Exemplary embodiments in accordance with principles of inventive concepts provide a method of testing a defect of through-silicon via (TSV) in a stack chip package.

According to exemplary embodiments in accordance with principles of inventive concepts, in a method of inspecting a stack chip package, a first chip is prepared. The first chip includes a through-silicon via, first pad electrodes connected to the through silicon via and probe pad electrodes connected to the through silicon via. A testing chip is prepared. The testing chip includes second pad electrodes that are arranged to correspond with the first pad electrodes. The testing chip is temporarily adhered to the first chip such that the second pad electrodes are electrically connected to the first pad electrode respectively, to form a stack structure wherein the probe pad electrodes are exposed to the outside. An electrical signal is applied to the exposed probe pad electrodes to inspect the through silicon via included in the first chip.

In exemplary embodiments in accordance with principles of inventive concepts, the method may further include removing the testing chip from the first chip when the through-silicon via turns out to be poor (that is, fails the test) as a result of the inspecting process.

In exemplary embodiments in accordance with principles of inventive concepts, the testing chip may be a chip designed to test for the presence of a defect of the though silicon via included in the first chip.

In exemplary embodiments in accordance with principles of inventive concepts, the testing chip may include wiring that connects the through silicon vias of the first chip to form a conductive connection line when the first chip and the testing chip are adhered to each other.

In exemplary embodiments in accordance with principles of inventive concepts, inspecting the through silicon via may include contacting a probe needle with the probe pad electrode and applying the electrical signal through the probe needle to detect whether or not the electrical signal is transmitted through the through-silicon vias of the conductive connection.

In exemplary embodiments in accordance with principles of inventive concepts, after inspecting the through-silicon via, the method may further include, when the through-silicon via turns out to be good (that is, passes the test) as a result of the inspecting process, separating the testing chip from the good first chip and stacking a real (that is, operational) second chip on the good first chip to form a stack-chip package.

In exemplary embodiments in accordance with principles of inventive concepts, a real second chip may be used for the testing chip.

In exemplary embodiments in accordance with principles of inventive concepts, the testing chip may be a separate chip that is diced from a wafer.

In exemplary embodiments in accordance with principles of inventive concepts, a bump pad may be formed on a surface of the first chip opposite to the surface where the first pad electrode is formed, to be electrically connected to the through-silicon via.

In exemplary embodiments in accordance with principles of inventive concepts, the method may include coating a first temporary adhesive layer on the surface of the first chip where the bump pad is formed, and adhering a carrier substrate using the first temporary adhesive layer to the first chip.

In exemplary embodiments in accordance with principles of inventive concepts, the probe pad electrode may have an upper surface area greater than an upper surface area of the first pad electrode.

In exemplary embodiments in accordance with principles of inventive concepts, when the through silicon via turns out to be good as a result of the inspecting process, the testing chip and the good first chip that are adhered to each other may be used to form a stack chip package.

In exemplary embodiments in accordance with principles of inventive concepts, the first chip may be formed in a substrate before being diced into a separate chip.

According to exemplary embodiments in accordance with principles of inventive concepts, in a method of inspecting a stack chip package, a first chip is prepared. The first chip includes a through-silicon via and first pad electrodes connected to the through-silicon via. A testing chip is prepared. The testing chip includes second pad electrodes arranged corresponding to the first pad electrodes, a second through-silicon via electrically connected to the second pad electrodes and probe pad electrodes electrically connected to the second through-silicon via and provided on a surface of the testing chip opposite to a surface where the second electrodes are formed. The testing chip is temporarily adhered to the first chip such that the second pad electrodes are electrically connected to the first pad electrode respectively, to form a stack structure wherein the probe pad electrodes are exposed to the outside. An electrical signal is applied to the exposed probe pad electrodes to inspect the through silicon via included in the first chip. The testing chip may be removed from the first chip when the through silicon via turns out to be poor as a result of the inspecting process.

In exemplary embodiments in accordance with principles of inventive concepts, the testing chip may be a separate chip that is diced from a wafer or a bare chip that is formed in a wafer before dicing the wafer.

According to exemplary embodiments in accordance with principles of inventive concepts, before finally bonding an upper chip to a lower chip, a defect of a through-silicon via for electrically connecting the chips may be inspected. Accordingly, an electrical testing process may be performed to select a good chip and then the selected good chip may be stacked to form the stack chip package, to thereby increase yields of products.

In an exemplary embodiment in accordance with principles of inventive concepts, a stack-chip package may be formed by adhering a test chip to a chip-under-test, testing the chip-under-test, and mating the chip-under-test with a second chip to form a stack-chip package if the chip-under-test passes the test.

In an exemplary embodiment in accordance with principles of inventive concepts, the testing chip may be an operational chip and it is left adhered to the chip-under-test to mate to the chip-under-test if the chip under test passes the test.

In an exemplary embodiment in accordance with principles of inventive concepts, the chip-under-test may be discarded if it fails the test.

In an exemplary embodiment in accordance with principles of inventive concepts, the testing chip may be separated from the chip-under-test if the chip-under-test fails the test and the testing chip may be subsequently adhered to another chip-under-test

In an exemplary embodiment in accordance with principles of inventive concepts, the testing chip is left adhered to the other chip-under-test to mate to the chip-under-test if the other chip-under-test passes the test.

### BRIEF DESCRIPTION OF THE DRAWINGS

Exemplary embodiments in accordance with principles of inventive concepts will be more clearly understood from the following detailed description taken in conjunction with the accompanying drawings. FIGS. 1 to 10 represent non-limiting, exemplary embodiments in accordance with principles of inventive concepts as described herein.

FIGS. 1 to 4 are cross-sectional views illustrating a method of inspecting a stack chip package in accordance with principles of inventive concepts.

FIGS. 5 to 7 are cross-sectional views illustrating various connection structures of a testing chip and a first chip in an exemplary embodiment in accordance with principles of inventive concepts.

FIG. 8 is a cross-sectional view illustrating a method of inspecting a stack chip package in an exemplary embodiment in accordance with principles of inventive concepts.

FIG. 9 is a cross-sectional view illustrating a method of inspecting a stack chip package in an exemplary embodiment in accordance with principles of inventive concepts.

FIGS. 10 and 11 are cross-sectional views illustrating a method of inspecting a stack chip package in an exemplary embodiment in accordance with principles of inventive concepts

FIGS. 12 to 19 are cross-sectional views illustrating a stack chip package in an exemplary embodiment in accordance with principles of inventive concepts.

FIG. 20 is a cross-sectional view illustrating a stack chip package in an exemplary embodiment in accordance with principles of inventive concepts.

FIG. 21A is a cross-sectional view illustrating a package module including a stack chip package having a memory device and a logic device. FIG. 21B is a perspective view illustrating the package module in FIG. 21A.

FIG. 22 is a plan view illustrating a package module including a stack chip package in an exemplary embodiment in accordance with principles of inventive concepts.

FIG. 23 is a block diagram illustrating a card including a stack chip package in an exemplary embodiment in accordance with principles of inventive concepts.

### DESCRIPTION

Exemplary embodiments in accordance with principles of inventive concepts will now be described more fully with reference to the accompanying drawings, in which exemplary embodiments are shown. Exemplary embodiments in accordance with principles of inventive concepts may, however, be embodied in many different forms and should not be construed as being limited to the embodiments set forth herein; rather, these embodiments are provided so that this disclosure will be thorough and complete, and will fully convey the concept of exemplary embodiments to those of ordinary skill in the art. In the drawings, the thicknesses of layers and regions may be exaggerated for clarity. Like reference numerals in the drawings denote like elements, and thus their description may not be repeated.

It will be understood that when an element is referred to as being “connected” or “coupled” to another element, it can be directly connected or coupled to the other element or intervening elements may be present. In contrast, when an element is referred to as being “directly connected” or “directly coupled” to another element, there are no intervening elements present. Like numbers indicate like elements throughout. As used herein the term “and/or” includes any and all combinations of one or more of the associated listed items. Other words used to describe the relationship between elements or layers should be interpreted in a like fashion (e.g., “between” versus “directly between,” “adjacent” versus “directly adjacent,” “on” versus “directly on”).

It will be understood that, although the terms “first”, “second”, etc. may be used herein to describe various elements, components, regions, layers and/or sections, these elements, components, regions, layers and/or sections should not be limited by these terms. These terms are only used to distinguish one element, component, region, layer or section from another element, component, region, layer or section. Thus, a first element, component, region, layer or section discussed below could be termed a second element, component, region, layer or section without departing from the teachings of exemplary embodiments.

Spatially relative terms, such as “beneath,” “below,” “lower,” “above,” “upper” and the like, may be used herein for ease of description to describe one element or feature's relationship to another element(s) or feature(s) as illustrated in the figures. It will be understood that the spatially relative terms are intended to encompass different orientations of the device in use or operation in addition to the orientation depicted in the figures. For example, if the device in the figures is turned over, elements described as “below” or “beneath” other elements or features would then be oriented “above” the other elements or features. Thus, the exemplary term “below” can encompass both an orientation of above and below. The device may be otherwise oriented (rotated 90 degrees or at other orientations) and the spatially relative descriptors used herein interpreted accordingly.

The terminology used herein is for the purpose of describing particular embodiments only and is not intended to be limiting of exemplary embodiments. As used herein, the singular forms “a,” “an” and “the” are intended to include the plural forms as well, unless the context clearly indicates otherwise. It will be further understood that the terms “comprises”, “comprising”, “includes” and/or “including,” if used herein, specify the presence of stated features, integers, steps, operations, elements and/or components, but do not preclude the presence or addition of one or more other features, integers, steps, operations, elements, components and/or groups thereof.

Exemplary embodiments in accordance with principles of inventive concepts are described herein with reference to cross-sectional illustrations that are schematic illustrations of idealized embodiments (and intermediate structures) of exemplary embodiments. As such, variations from the shapes of the illustrations as a result, for example, of manufacturing techniques and/or tolerances, are to be expected. Thus, exemplary embodiments in accordance with principles of inventive concepts should not be construed as limited to the particular shapes of regions illustrated herein but are to include deviations in shapes that result, for example, from manufacturing. For example, an implanted region illustrated as a rectangle may have rounded or curved features and/or a gradient of implant concentration at its edges rather than a binary change from implanted to non-implanted region. Likewise, a buried region formed by implantation may result in some implantation in the region between the buried region and the surface through which the implantation takes place. Thus, the regions illustrated in the figures are schematic in nature and their shapes are not intended to illustrate the actual shape of a region of a device and are not intended to limit the scope of exemplary embodiments.

Unless otherwise defined, all terms (including technical and scientific terms) used herein have the same meaning as commonly understood by one of ordinary skill in the art to which exemplary embodiments in accordance with principles of inventive concepts belong. It will be further understood that terms, such as those defined in commonly-used dictionaries, should be interpreted as having a meaning that is consistent with their meaning in the context of the relevant art and will not be interpreted in an idealized or overly formal sense unless expressly so defined herein.

Hereinafter, semiconductor devices and methods of fabricating the same according to exemplary embodiments in accordance with principles of inventive concepts will now be described more fully with reference to the accompanying drawings.

Exemplary embodiments in accordance with principles of inventive concepts are described herein with reference to cross-sectional illustrations that are schematic illustrations of idealized exemplary embodiments in accordance with principles of inventive concepts (and intermediate structures). As such, variations from the shapes of the illustrations as a result, for example, of manufacturing techniques and/or tolerances, are to be expected. Thus, exemplary embodiments in accordance with principles of inventive concepts should not be construed as limited to the particular shapes of regions illustrated herein but are to include deviations in shapes that result, for example, from manufacturing. For example, an implanted region illustrated as a rectangle will, typically, have rounded or curved features and/or a gradient of implant concentration at its edges rather than a binary change from implanted to non-implanted region. Likewise, a buried region formed by implantation may result in some implantation in the region between the buried region and the surface through which the implantation takes place. Thus, the regions illustrated in the figures are schematic in nature and their shapes are not intended to illustrate the actual shape of a region of a device and are not intended to limit the scope of exemplary embodiments in accordance with principles of inventive concepts.

Unless otherwise defined, all terms (including technical and scientific terms) used herein have the same meaning as commonly understood by one of ordinary skill in the art to which exemplary embodiments in accordance with principles of inventive concepts belong. It will be further understood that terms, such as those defined in commonly used dictionaries, should be interpreted as having a meaning that is consistent with their meaning in the context of the relevant art and will not be interpreted in an idealized or overly formal sense unless expressly so defined herein.

Hereinafter, exemplary embodiments in accordance with principles of inventive concepts will be explained in detail with reference to the accompanying drawings.

Exemplary embodiments in accordance with principles of inventive concepts are described herein to include two chips, however, the number of the stacked chips is not limited thereto. Exemplary embodiments in accordance with principles of inventive concepts relate to the inspection and detection of a defect of a though-silicon via included in stacked chips. In exemplary embodiments in accordance with principles of inventive concepts, a chip including a through-silicon via may be a bare chip that is formed in a wafer before dicing the wafer or a separate chip that is diced from a wafer, for example.

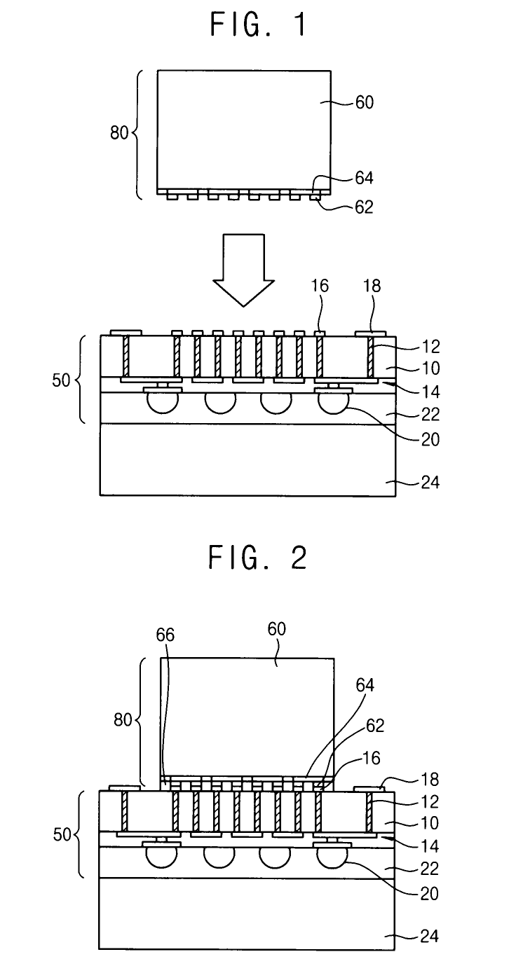

The cross-sectional views of FIGS. 1 to 4 depict an exemplary method in accordance with principles of inventive concepts of a method of inspecting a stack-chip package.

Referring to FIG. 1, a substrate 10 including first chip(s) 50 formed therein may be prepared. First chip 50 may include circuits (not illustrated) of a semiconductor device, through-silicon vias 12 penetrating substrate 10, first pad electrodes 16, probe pad electrodes 18 and micro bump pads 20. First chip 50 may also be referred to herein as target chip 50, or chip under test 50.

The circuits may be provided in a first surface of substrate 10. Wiring 14 (also referred to herein as interconnect) may be connected to through silicon via 12 that is exposed from the first surface of substrate 10.

First pad electrode 16 may be provided on a second surface of the substrate 10 opposite to the first surface. First pad electrode 16 may make contact with through-silicon via 12 that is exposed from the second surface of substrate 10. First pad electrode 16 may extend from the second surface of substrate 10. Because first pad electrode 16 has a relatively small upper surface and the distance between first pad electrodes 16 is relatively small, it may be difficult for a probe needle to make contact with first pad electrode 16.

Probe pad electrode 18 may be connected to through-silicon via 12 that is exposed from the second surface of the substrate 10. Probe pad electrode 18 may have an upper surface area greater than the upper surface area of first pad electrode 16, the greater area allowing a probe needle to more securely make contact with probe pad electrode 18. Probe pad electrodes 18 may be formed in a peripheral region of substrate 10 to allow for secure contact between probe needles and probe pad electrodes 18 without compromising first chip 50.

Micro bump pad(s) 20 may be provided on the first surface of substrate 10 to make contact with wiring 14 formed on the first surface of the substrate 10.

In an exemplary embodiment in accordance with principles of inventive concepts, first chip 50, including through-silicon vias 12, may be a target chip to be inspected.

A first temporary adhesive layer 22 may be formed on substrate 10 of first chip 50 to cover micro bump pad 20. A carrier substrate 24 may be adhered to substrate 10 by first temporary adhesive layer 22.

A testing chip 80 may be provided to inspect through-silicon vias 12 included in first chip 50 and/or the circuit connected to through-silicon vias 12. In an exemplary embodiment in accordance with principles of inventive concepts, a chip designed specifically to test for defects in though-silicon via(s) 12 may be used for the testing chip 80. Testing chip 80 may be configured, for example, to determine whether or not through-silicon vias 12 are connected to targeted locations in interconnect 14. For example, adjacent through-silicon vias 12 may be connected to each other in a probing state by testing chip 80. Accordingly, in the probing state, electrical signals applied to probe pad electrode 18 may be detected to determine whether or not through-silicon vias 12 are defective. As illustrated in FIG. 1 through FIG. 4, testing chip 80 may be a separate chip that is diced from a wafer (substrate), for example. Testing chip 80, designed specifically for testing chip-under-test 50, may have a form factor that is similar to an operational chip (not shown) that is to be mated to, or stacked with, chip-under-test 50, should chip-under-test 50, interconnect 14, and through-silicon via 12 pass inspection, for example.

In an exemplary embodiment in accordance with principles of inventive concepts, testing chip 80 may include a second substrate 60 and second pad electrode 62. In a probing state, second pad electrode 62 may make contact with first pad electrode 16. Testing chip 80 may include a connection wiring 64 (also referred to herein as interconnection 64) that connects second pad electrodes 62 to one another in a prescribed manner. When second pad electrode 62 makes contact with first pad electrode 16, first and second pad electrodes 16, 62, connection pads 64, and through-silicon vias 12 may be connected serially to one another to form a connection line, for example. Second pad electrode 62 may be positioned and shaped to protrude from second substrate 60 corresponding to first pad electrode 16.

Referring to FIG. 2, in an exemplary embodiment in accordance with principles of inventive concepts, first chip 50 may be adhered to testing chip 80 by a second temporary adhesive layer 66 to stack testing chip 80 on first chip 50. First pad electrodes 16 of first chip 50 may make contact with second pad electrodes 62 of testing chip 80, respectively.

In an exemplary embodiment in accordance with principles of inventive concepts, second temporary adhesive layer 66 may include a photocurable adhesive layer, a thermosetting adhesive layer, a thermoplastic adhesive layer, a release layer, etc., for example.

In an exemplary embodiment in accordance with principles of inventive concepts, first temporary adhesive layer may be left intact when second temporary adhesive layer 66 is removed after a test step in the testing of chip 50. Second temporary adhesive layer 66 may be formed using a material different from that of first temporary adhesive layer 22. Alternatively, even if second temporary adhesive layer 66 is formed using a material having the same adhesive type as first temporary adhesive layer 22, second temporary adhesive layer 66 may have a different property, such as adhesive force or glass transition temperature, from the first temporary layer 22, for example.

In an exemplary embodiment in accordance with principles of inventive concepts wherein second temporary adhesive layer 66 includes a thermoplastic adhesive layer, a thermoplastic resin may be coated on the substrate of first chip 50, and then, the coated thermoplastic resin may be baked to adhere the testing chip to the first chip 50.

In an exemplary embodiment in accordance with principles of inventive concepts wherein second temporary adhesive layer 66 includes a photocurable adhesive layer, a photocurable resin may be coated on the substrate of first chip 50, and then, the coated photocurable resin may be exposed to UV light to adhere testing chip 80 to first chip 50.

Testing chip 80 may be adhered to first chip 50 in a manner that leaves probe pad electrode 18 exposed outside the perimeter of testing chip 80, for example, allowing a probe needle access to probe pad electrode 18 even while testing chip 80 is in place.

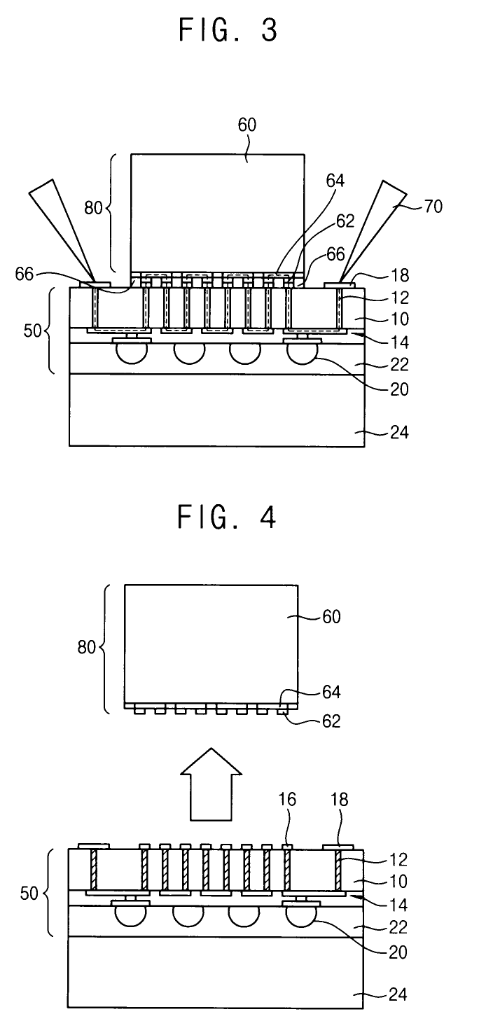

Referring to FIG. 3, when probe needle 70 probes probe pad electrode 18, an electrical signal may be applied to probe pad electrode 18, to inspect, or determine, whether or not through-silicon via 12 is defective and/or whether first chip 50 is defective.

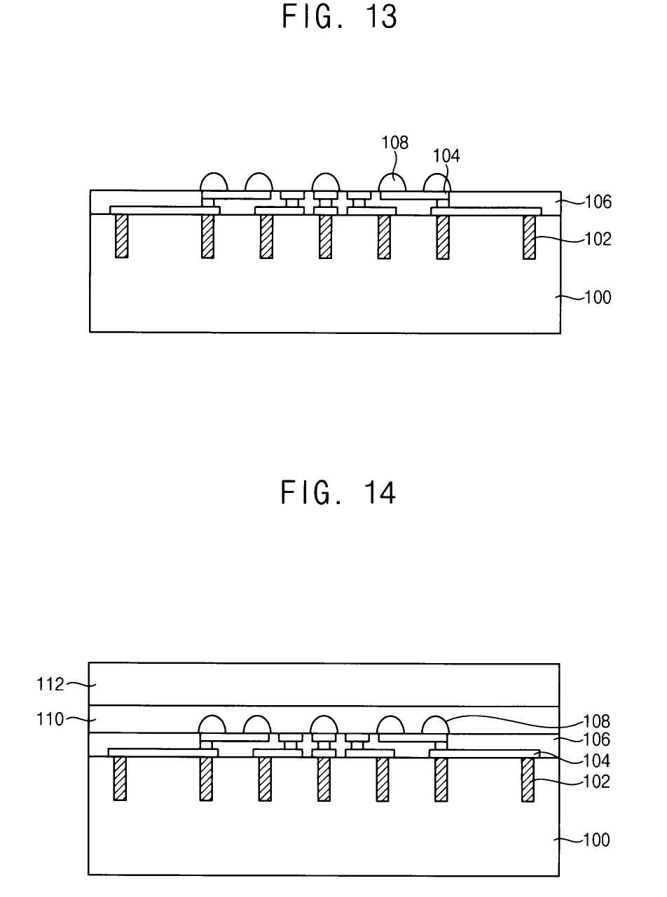

In an exemplary embodiment in accordance with principles of inventive concepts, first chip 50 may be inspected by probing of probe needle 70 while testing chip 80 is in place, obviating a separate chip-inspection test step associated with probe pad electrodes 18 that arc inaccessible to probe needle 70 while testing chip 80 is in place, such as described in the discussion related to FIG. 11.///re-check this after FIG. 11, it may just be sequence///

In an exemplary embodiment in accordance with principles of inventive concepts, when testing chip 80 is adhered to first chip 50, through-silicon vias 12 may be connected serially to one another to form one connection line. Accordingly, an electrical signal may be transmitted through the connection line and the electrical signal may be detected to determine whether or not through-silicon via 12 is defective and/or first chip 50 is defective.

After completing a testing process, as illustrated in FIG. 4, second temporary adhesive layer 66 may be removed to separate testing chip 80 from first chip 50.

The method of removing second temporary adhesive layer 66 may be determined based on the material of second temporary adhesive layer 66. If, for example, second temporary adhesive layer 66 includes a thermoplastic adhesive layer, second temporary adhesive layer 66 may be heated to separate testing chip 80 from first chip 50, and then, a cleaning solution may be used to remove the remaining second temporary adhesive layer 66. Alternatively, if, for example, second temporary adhesive layer 66 includes a photocurable adhesive layer, a laser may be irradiated on second temporary adhesive layer 66 to separate testing chip 80 from first chip 50.

In accordance with principles of inventive concepts, first chips 50, or chips under test 50, that pass inspection are mated with a second, operational (that is to say, non-testing) chip to form an operational chip-stack, or stack-chip package. According to exemplary embodiments in accordance with principles of inventive concepts, in this manner, only “good” first chips 50 are bonded to a second, operational, chip, thereby avoiding the waste of “good” second chips that otherwise would be bonded to “bad,” or failed, first chips. Conventionally, a chip-stack is formed (that is, first and second operational chips are bonded), then electrical testing is performed on the chip-stack. The chip-stack is then tested and, if the chip-stack fails electrical tests, the entire chip-stack may be discarded. Such a process may lead to waste of “good” chips when, for example, a good second chip is bonded to a bad first chip and both chips in the stack are discarded because the bad first chip causes the chip stack to fail electrical tests. In contrast, in accordance with principles of inventive concepts, only good first operational chips are bonded to second operational chips, thereby avoiding the waste of good second operational chips that might otherwise occur.

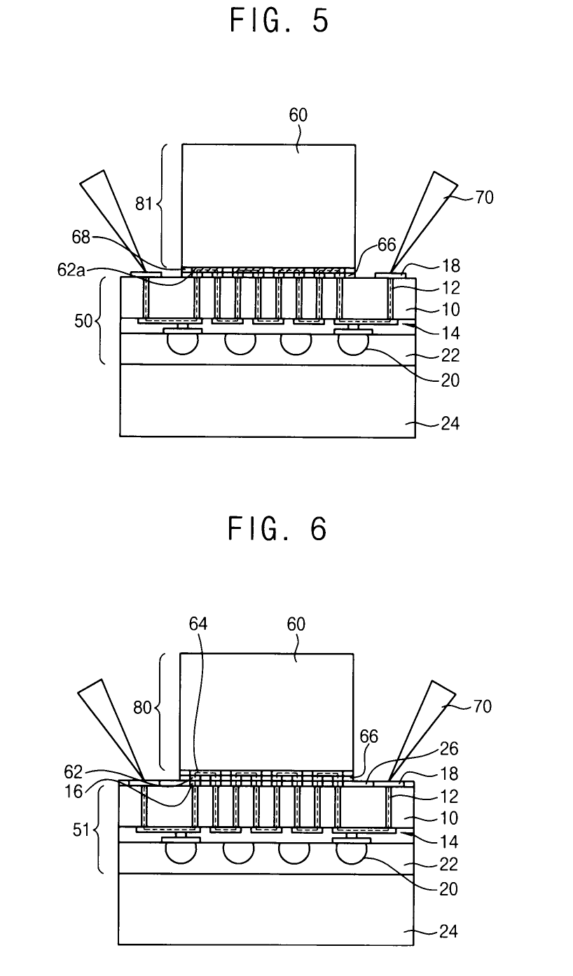

In accordance with principles of inventive concepts, testing chip and first chip may have various shapes as described below. Hereinafter, various testing chips or first chips having different shapes from those in FIG. 1 will be described with reference to FIGS. 5 to 7. In accordance with principles of inventive concepts, a method of inspecting a through-silicon via of a first chip may be substantially the same as the processes that have been explained with reference to FIGS. 1 to 4.

FIGS. 5 to 7 are cross-sectional views illustrating various connection structures of an exemplary embodiment of testing chip and a first chip in accordance with principles of inventive concepts.

In an exemplary embodiment in accordance with principles of inventive concepts as illustrated in FIG. 5, a second pad electrode 62a may not have a shape protruding from testing chip 81. In particular, second pad electrode 62a may have an upper surface coplanar with an upper surface of an insulation layer 68 formed between second pad electrodes 62a of testing chip 81. When testing chip 81 is adhered temporarily to first chip 50, second pad electrode 62a may connect adjacent first pad electrodes 16 to each other. In such an embodiment, connection wiring 64 as illustrated in FIG. 1 may be omitted.

In an exemplary embodiment in accordance with principles of inventive concepts, testing chip 81 may be adhered to first chip 50, to provide a connection line as described in the discussion related to FIG. 3.

In an exemplary embodiment in accordance with principles of inventive concepts as illustrated in FIG. 6, a first pad electrode 16 may not have a shape protruding from first chip 51, also referred to herein as chip under test 51. In particular, first pad electrode 16 may have an upper surface coplanar with an upper surface of an insulation layer 26 formed between first pad electrodes 16 of first chip 51.

In an exemplary embodiment in accordance with principles of inventive concepts testing chip 60 may be substantially the same as testing chip 60 described in the discussion related to FIG. 1.

Testing chip 60 may be adhered to first chip 51, to provide a connection line, as described in the discussion related to FIG. 3.

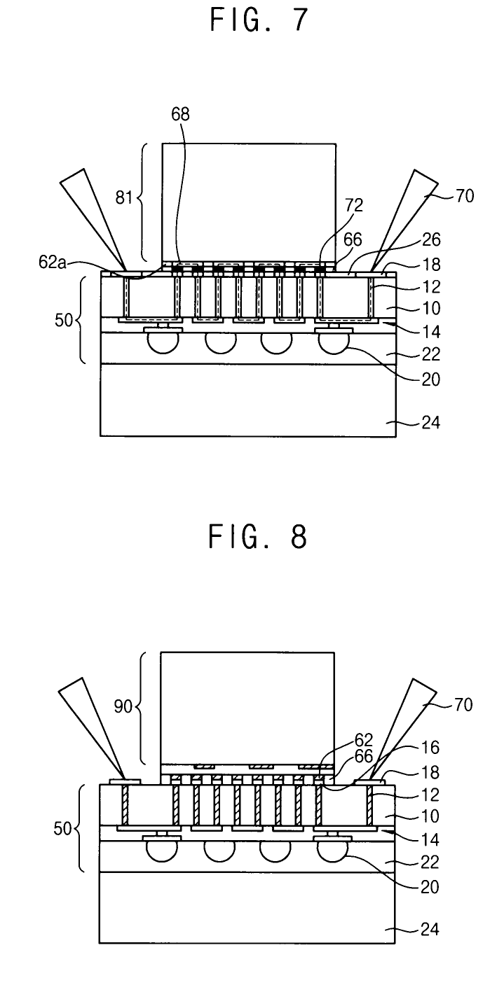

In an exemplary embodiment in accordance with principles of inventive concepts as illustrated in FIG. 7, a first pad electrode 16 and a probe pad electrode 18 may not have a shape protruding from a first chip 50. In particular, first pad electrode 16 may have an upper surface coplanar with an upper surface of an insulation layer 26 formed between first pad electrodes 16.

Second pad electrode 62a may not have a shape protruding from testing chip 81. In particular, second pad electrode 62a may have an upper surface coplanar with an upper surface of insulation layer 68 formed between second pad electrodes 62a of testing chip 81. When testing chip 81 is adhered temporarily to first chip 50, second pad electrode 62a may connect adjacent first pad electrodes 16 to each other.

In an exemplary embodiment in accordance with principles of inventive concepts as illustrated in, testing chip 81 may be adhered to first chip 50 by a second adhesive layer 66. Second adhesive layer 66 may include conductive ball(s) 72. Conductive ball 72 may be provided between first and second pad electrodes 16, 62a. First pad electrode 16 may be electrically connected to second pad electrode 62a by conductive ball 72, for example.

Testing chip 81 may be adhered to first chip 50, to provide a connection line as described in the discussion related to FIG. 3.

The present exemplary embodiment in accordance with principles of inventive concepts may be substantially the same as described in the discussion related to FIGS. 1-7, except that a real second chip (that is, an operational second chip, not a second chip designed specifically for testing) is used to inspect a first chip (also referred to herein as a chip under test), or a through-silicon via, without using a testing chip (that is, without using a chip specifically designed for testing the chip under test, with no further function).

An exemplary embodiment in accordance with principles of inventive concepts of inspecting a stack-chip package will be described with reference to the cross-sectional view of FIG. 8.

In an exemplary embodiment in accordance with principles of inventive concepts as illustrated in FIG. 8, a second chip 90 may be provided to be stacked on a first chip 50. Second chip 90 may be a “good” chip, that is, an operational chip that has been tested and determined to operate properly. In an exemplary embodiment, second chip 90 may be a separate chip that is diced from a wafer (substrate). Second pad electrode 62 may be formed on second chip 90 to be connected to a corresponding first pad electrode 10 of first chip 50.

First chip 50 and second chip 90 may be adhered to each other by a second temporary adhesive layer 65 such that first pad electrode 16 is connected to second pad electrode 62. In an exemplary embodiment, a probe pad electrode 18 provided on first chip 50 may be exposed for testing even when first chip 50 is adhered to second chip 90.

When a probe needle 70 probes probe pad electrode 18, an electrical signal may be applied to probe pad electrode 18, to determine whether or not first chip 50 or a connection between first chip 50 and second chip 90 is defective.

In an exemplary embodiment in accordance with principles of inventive concepts, if the test determines that first chip 50 and the connection between first and second chips 50, 90 are good, first and second chips 50, 90 may be used to form a stack-chip package. When subsequent processes are performed to complete the stack chip package, first chip 50 and the second chip 90 may be adhered to each other by second temporary adhesive layer 66, for example.

If testing determines that first chip 50 and/or the connection between first and second chips 50, 90 are poor, second temporary adhesive layer 66 may be removed to separate the first chip 50 from the second chip 90. Then, first chip may fall be discarded and second chip 90 (which, in this exemplary embodiment, has already been determined to be a good chip) may be bonded to another first chip, which chip may be determined to be a good chip according to an exemplary test process just described.

In exemplary embodiment in accordance with principles of inventive concepts, even if first chip 50 is determined poor (that is, fails the test), second chip 90 may be used with another, good, first chip 50 to form a stack chip package.

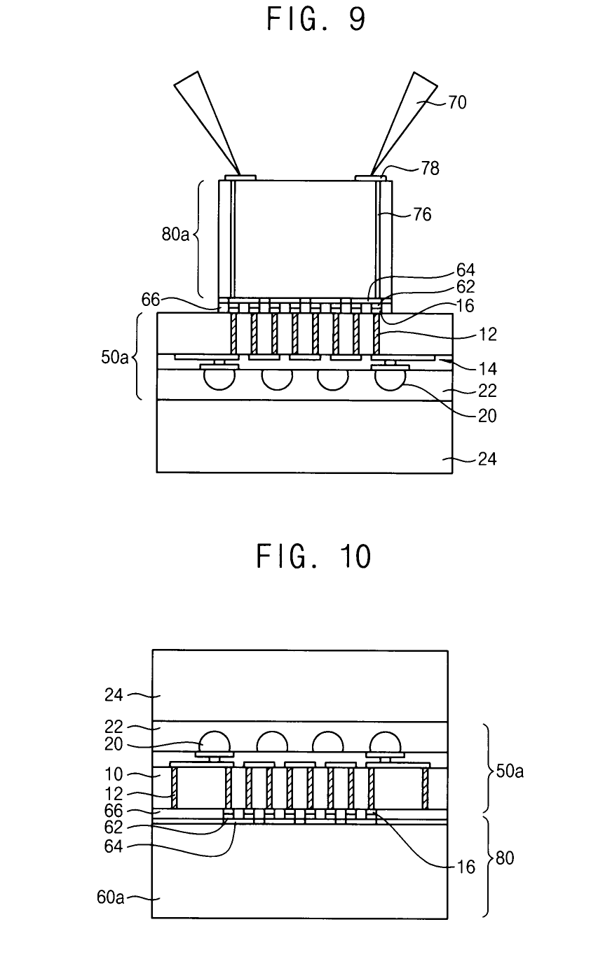

An exemplary embodiment of a method of inspecting a stack-chip package in accordance with principles of inventive concepts is illustrated in the cross-sectional view of FIG. 9.

Referring to FIG. 9, a substrate 10 including first chips 50a formed therein may be prepared.

First chip 50a may include first through-silicon vias 12 penetrating substrate 10. First pad electrodes 16 may be provided on a second surface of substrate 10. First pad electrode 16 may make contact with first through-silicon via 12 that is exposed from the second surface of substrate 10. Micro bump pads 20 may be provided on a first surface of substrate 10 opposite to the first surface. A carrier substrate 24 may be adhered to the first surface of substrate 10 by a first temporary adhesive layer 22. As illustrated in the exemplary embodiment in accordance with principles of inventive concepts of FIG. 9, a probe pad electrode may not be formed on the first chip 50a.

A testing chip 80a may be provided to inspect/test first through-silicon vias 12 included in first chip 50a and/or circuits connected to through-silicon vias 12. Testing chip 80a may be a chip designed specifically to test for defects in first though-silicon via 12, for example. Alternatively, testing chip 80a may be an operational chip to be stacked on first chip 50a for manufacturing a stack-chip package.

In an exemplary embodiment in accordance with principles of inventive concepts, testing chip 80a may be a separate chip that is diced from a wafer (substrate), for example. Alternatively, testing chip 80a may be a bare chip that is formed in a wafer before dicing the wafer.

In an exemplary embodiment in accordance with principles of inventive concepts where testing chip 80a is designed specifically for testing first through-silicon via 12, second pad electrode 62 and connection wiring 64 may be provided on a first surface of testing chip 80a. Second pad electrode 62 may be connected to the corresponding first pad electrode 16 of first chip 50a. A second through-silicon via 76 may be provided in testing chip 80a to be electrically connected to second pad electrode 62. A probe pad electrode 78 may be provided on a second surface of testing chip 80a opposite to the first surface to be electrically connected to second through-silicon via 76.

In an exemplary embodiment in accordance with principles of inventive concepts, testing chip 80a may be adhered to first chip 50a by a second temporary adhesive layer 66 such that second pad electrodes 62 are connected to first pad electrodes 16, respectively. When testing chip 80a is adhered to the first chip 50a, probe pad electrode 78 on the surface of testing chip 80a may be exposed for access by needle probe 70, for example. When testing chip 80a is adhered to first chip 50a, second through-silicon via 76, first and second pad electrodes 16, 62, and first through-silicon vias 12 may be connected serially to one another to form one connection chain, for example.

After such connection is made, probe needle 70 may probe probe pad electrode 78 of testing chip 80a to apply electrical signals. The electrical signals may be applied to probe pad electrode 78, to determine whether or not first through-silicon via 12 and/or first chip 50a is defective.

After completing the testing process, second temporary adhesive layer 66 may be removed to separate testing chip 80a from first chip 50a.

After separating testing chip 80a and first chip 50a, although it is not illustrated in the figures, an electrical testing process may be performed on the first chips to select a good first chip, and then, a second chip may be stacked on the selected good first chip, to complete a stack chip package. In an exemplary embodiment in accordance to principles of inventive concepts, the second chip may be a good chip that is selected after performing an electrical testing process on it. Accordingly, in an exemplary embodiment only a good second chip is stacked on a good first chip to form stack-chip package that has a high probability of being “good” (that is, not failing).

A first chip that is determined by the electrical testing process to fail, may be discarded and, as a result, in accordance with principles of inventive concepts an electrical testing process may be performed on the first chip before performing a bonding process with a second chip, to thereby prevent an unnecessary waste of a good second chip.

An operational second chip, as opposed to a second chip designed specifically for testing, may be used for a testing chip. In such an embodiment in accordance with principles of inventive concepts, when the first chip and the connection between the first and second chips have been tested and proven to be good, the first and second chips may be used to form a stack chip package. On the other hand, if the first chip and/or the connection between the first and second chips are poor (that is, fail testing), the second temporary adhesive layer may be removed to separate the first chip from the second chip. Then, the first chip may be discarded and the second chip (good chip) may be bonded to another, good, first chip to form a stack chip package.

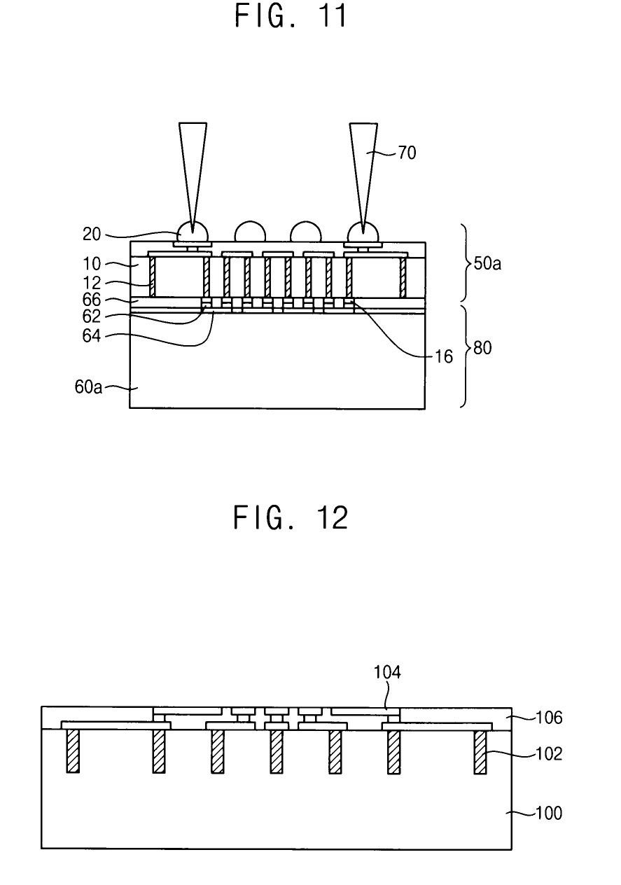

An exemplary embodiment of a method of inspecting a stack-chip package in accordance with principles of inventive concepts is depicted in the cross-sectional views of FIGS. 10 and 11.

Referring to FIG. 10, a substrate 10 including first chips 50a formed therein may be prepared. First chip 50a may include first through-silicon vias 12 penetrating substrate 10. First pad electrodes 16 may be provided on a second surface of substrate 10. First pad electrode 16 may make contact with first through-silicon via 12 that is exposed from the second surface of substrate 10. Micro bump pads 20 may be provided on a first surface of substrate 10 opposite to the first surface. A carrier substrate 24 may be adhered to the first surface of substrate 10 by a first temporary adhesive layer 22. In an exemplary embodiment in accordance with principles of inventive concepts, a probe pad electrode may not be formed on, that is, may be left off, first chip 50a.

A testing chip 80a may be provide to inspect first through-silicon vias 12 included in first chip 50a and/or circuits connected to through-silicon vias 12. Testing chip 80a may be a chip specifically designed to test for defects in first though-silicon via 12 or may be an operational chip to be stacked on first chip 50a for manufacturing a stack chip package.

In an exemplary embodiment in which testing chip 80a is designed specifically for testing, testing chip 80a may be a bare chip that is formed in a wafer, not a separate chip that is diced from a wafer (substrate). Second pad electrode 62 and connection wiring 64 may be provided on a first surface of testing chip 80a. Second pad electrode 62 may be connected to the corresponding first pad electrode 16 of first chip 50a.

Testing chip 80a may be adhered to first chip 50a by a second temporary adhesive layer 66 such that second pad electrodes 62 are connected to first pad electrodes 16 respectively.

Referring to FIG. 11, first temporary adhesive layer 22 may be removed to separate carrier substrate 24 from first chip 50a, to expose micro bump pad 20 to the outside.

Then, probe needle 70 may probe micro bump pad 20 to apply electrical signals. The electrical signals may be applied to micro bump pad 20, to determine whether or not the first through-silicon via 12 is defective and/or first chip 50a is defective.

After completing the testing process, second temporary adhesive layer 66 may be removed to separate testing chip 80a from the first chip 50a.

Then, although it is not illustrated in the figures, an electrical testing process may be performed on the first chips to select a good first chip, and then, a second chip may be stacked on a selected good first chip, to complete a stack-chip package. Accordingly, in an exemplary embodiment in accordance with principles of inventive concepts, the second chip may be stacked on only a good first chip to form the stack chip package, to thereby prevent a failure of the final stack-chip package.

A first chip that fails electrical testing may be discarded, for example. Therefore, electrical testing is performed on the first chip before performing a permanent bonding process with a second chip, to thereby prevent an unnecessary disuse of a good second chip.

Alternatively, an operational second chip may be used as a testing chip. In such an embodiment, when the first chip and the connection between the first and second chips are good, the first and second chips may be used to form a stack-chip package. On the other hand, if the first chip and the connection between the first and second chips are poor, that is, if they fail electrical testing, the second temporary adhesive layer may be removed to separate the first chip from the second chip. Then, the first chip may be discarded and the second chip (good chip) may be bonded to another (good) first chip.

Hereinafter, an exemplary method of manufacturing a stack chip package in accordance with principles of inventive concepts will be explained.

A stack-chip package, and formation thereof, in accordance with principles of inventive concepts in depicted in the cross-sectional views of FIGS. 12 to 19.

Referring to FIG. 12, a single crystalline silicon substrate 100 (hereinafter, referred to as a first substrate) including a first surface and a second surface opposite to the first surface may be prepared. Circuits may be formed in the first surface of first substrate 100. A wafer process (FEOL (front-end-of-line) process) may be performed to form circuit patterns and wirings on the first surface of first substrate 100.

Then, a preliminary through-silicon via 102 may be formed on the first surface of first substrate 100. Preliminary through-silicon via 102 may be formed to have a predetermined depth from the first surface. The preliminary through-silicon via 102 may be formed using a metal layer including aluminum, copper, or other metal, for example.

After forming preliminary through-silicon via 102, a wiring process (BEOL (back-end-of-line) process) may be performed to form an upper wiring layer and a protecting layer on the first surface of first substrate 100. Through the wiring process, a metal wiring 104 may be formed to be connected to preliminary through-silicon via 102. Metal wiring 104 may include aluminum, copper, or other metal, for example. Metal wiring 104 may be formed in an insulation interlayer 106.

Referring to FIG. 13, an outer connection pad may be formed on metal wiring 104. The outer connection pad may include a micro bump pad 108.

Referring to FIG. 14, a protecting layer may be formed to cover micro bump pad 108 on the first surface of first substrate 110. In particular, a first temporary adhesive layer 110 may be coated on the first surface of first substrate 100, and a carrier substrate 112 may be adhered to first substrate 100 by first temporary adhesive layer 110. Carrier substrate 112 may serve as a protecting member that protects the structures formed on the first surface of first substrate 100 and may serve as a handling substrate for a following process.

Referring to FIG. 15, the second surface of first substrate 100 may be partially removed until preliminary through-silicon via 102 is exposed, to form a through-silicon via 102a that penetrates first substrate 100a.

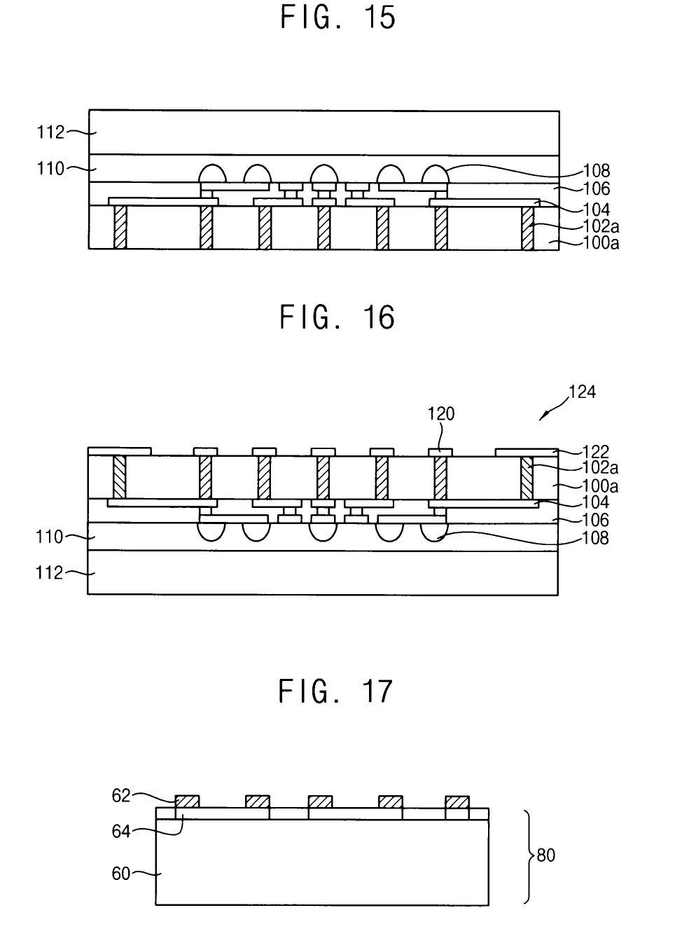

Referring to FIG. 16, a first pad electrode 120 may be formed to be electrically connected to through silicon via 102a that is exposed from the second surface of first substrate 100a.

A probe pad electrode 122 may be formed to be connected to through-silicon via 102a. Probe pad electrode 122 may be provided to serve as a probing pad for inspecting for defects in through-silicon vias 102a. Since a probe needle makes contact with an upper surface of probe pad electrode 122, the upper surface of probe pad electrode 122 may be implemented having a relatively large area. First pad electrode 120 may be formed using a metal such as aluminum, copper, or other metal, for example. Thus, a first chip 124 including through-silicon via 102a, first pad electrode 120, and probe electrode 122 may be formed.

Referring to FIG. 17, a testing chip 80 for inspecting first chip 124 may be formed on second substrate 60. Connection wirings 64 may be formed on second substrate 60. Second pad electrodes 62 may be formed to be connected to connection wiring 64. Second pad electrode 62 may be formed corresponding to first pad electrode 120. Second pad electrode 62 and connection pad 64 may be substantially the same as those that were described in the discussion related to FIG. 1, for example.

A dicing process may be performed on second substrate 60 to form a separate testing chip 80. In an exemplary embodiment in accordance with principles of inventive concepts, a testing chip 80 diced from second substrate 60 may have an area smaller than that of first chip 124.

After the testing chip 80 is adhered to the first chip, an electrical testing process may be performed as described in the discussion related to FIGS. 1-4, for example.

As described in the discussion related to FIG. 2, testing chip 80 may be adhered to first chip 124 by a second temporary adhesive layer 66. Accordingly, second pad electrodes 62 of testing chip 80 may be electrically connected to first pad electrodes 16 of first chip 124 respectively.

As described in the discussion related to FIG. 3, a probe needle may probe probe pad electrode 122, and then electrical signals may be applied to probe pad electrode 122, to determine whether or not first through-silicon via 102a of first chip 124 and/or first chip 124 is defective.

As described in the discussion related to FIG. 4, second temporary adhesive layer 66 may be removed to separate testing chip 80 from first chip 124.

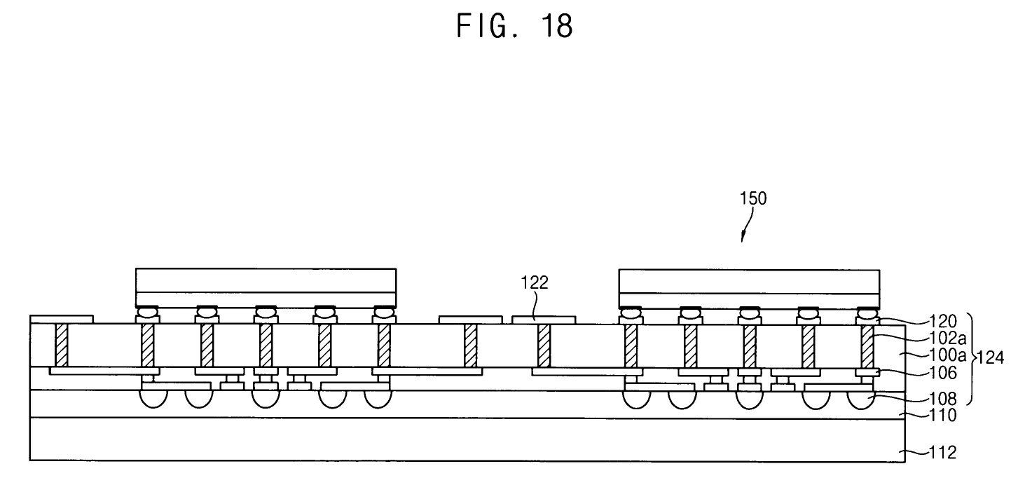

In an exemplary embodiment in accordance with principles of inventive concepts, electrical testing may be performed on “fist chips” to select a good first chip, then a second chip 150 (for example, a “known good” second chip) may be stacked on the selected good first chip to complete a stack-chip package, as illustrated in the cross-sectional view of FIG. 18. In such an exemplary embodiment, second chip 150 may be a good chip that is selected after performing an electrical testing process. A first chip that fails the electrical testing process may be discarded, for example.

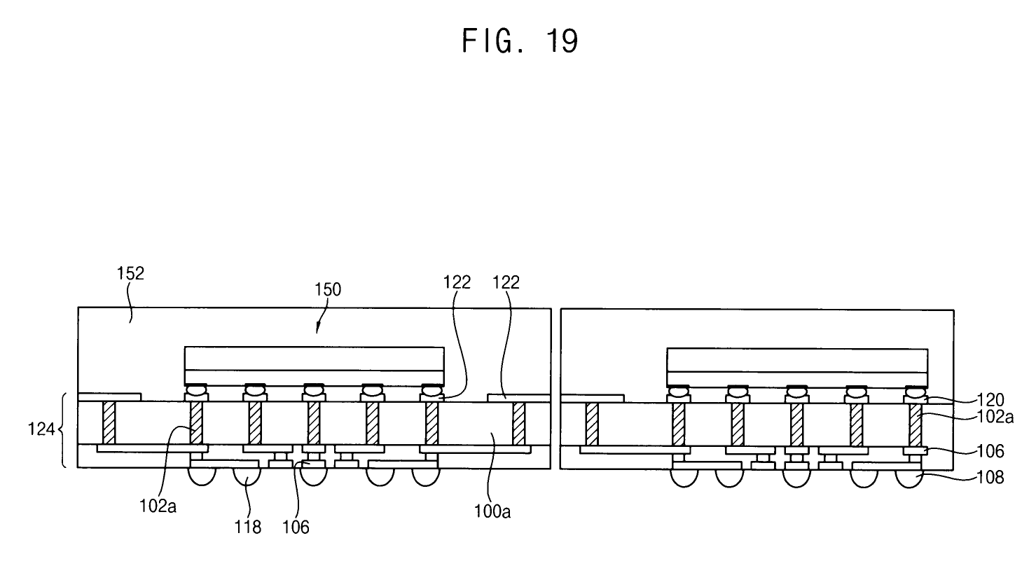

Referring to the exemplary embodiment of FIG. 19, a molding layer 152 may be formed to cover first chip 124 and second chip 150, in order to protect first and second chips 124, 150, for example.

After forming molding layer 152, a sawing process may be performed on first substrate 100a to dice the stacked chips. First temporary adhesive layer 110 and carrier substrate 112 may be removed to expose micro bump pad 108. Then, the diced stacked chips may be packaged to form a stack chip package.

As previously described, in accordance with principles of inventive concepts, an electrical testing process may be performed on first chips to select a good first chip before stacking a good second chip on the good first chip, to thereby increasing the yield of stacked-chips.

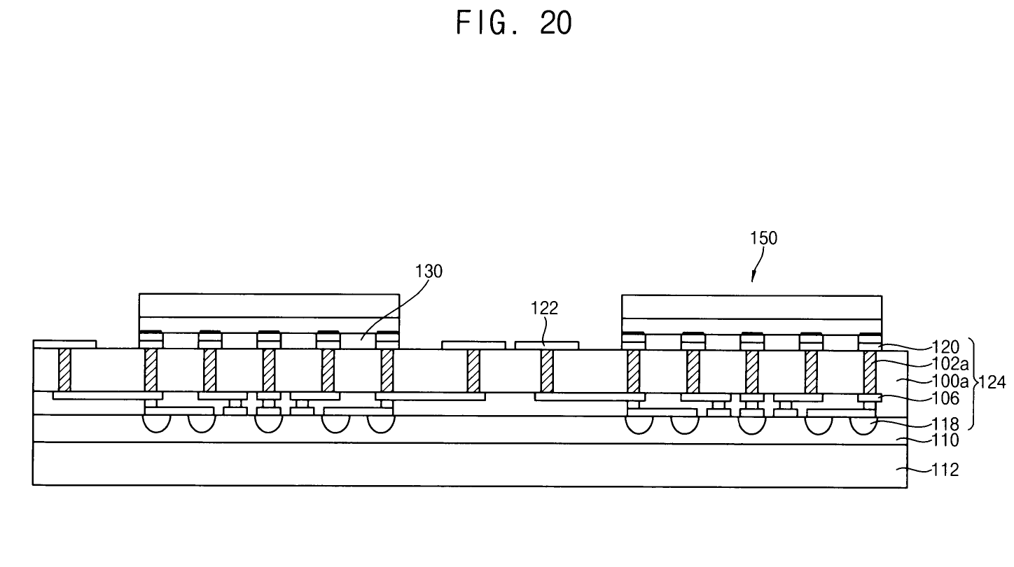

FIG. 20 is a cross-sectional view illustrating a stack chip package in accordance with a an exemplary embodiment in accordance with principles of inventive concepts. The present embodiment may be substantially the same as the embodiment described in the discussion related to FIGS. 12-19, except that an operational second chip is used to inspect a through-silicon via rather than a test chip specifically designed for testing.

In this exemplary embodiment, the same processes as described with reference to FIGS. 12 to 16 may be performed to form a first chip. Then, after real .second chips are formed on a second substrate, a dicing process may be performed to form a separate operational second chip 150.

In an exemplary embodiment in accordance with principles of inventive concepts such as described in the discussion related to FIG. 2, after second chip 150 is adhered temporarily to first chip 124, the through-silicon via of the first chip may be inspected.

In particular, a second temporary adhesive layer 130 may be coated on the first substrate, and then, second chip 150 may be adhered to the first chip by second temporary adhesive layer 130. A probe needle may make contact with the probe pad electrode, and then, electrical signals may be applied to determine whether or not first chip 124 and/or a connection between first chip 124 and second chip 150 is defective.

If the first chip and the connection between the first and second chips are good, the first and second chips 124, 150 may be used to form a stack-chip package, as illustrated in FIG. 20.

On the other hand, if the first chip and/or the connection between the first and second chips fail the test, second chip 150 may be separated from first chip 124. Then, the defective first chip be discarded and second chip 90 (good chip) may be bonded to another (good) first chip. In such an embodiment, even though the first chip is determined to be defective, second chip 150 may be used to form a stack-chip package.

In accordance with principles of inventive concepts, a stack chip package including a through-silicon via may be used as a system in package.

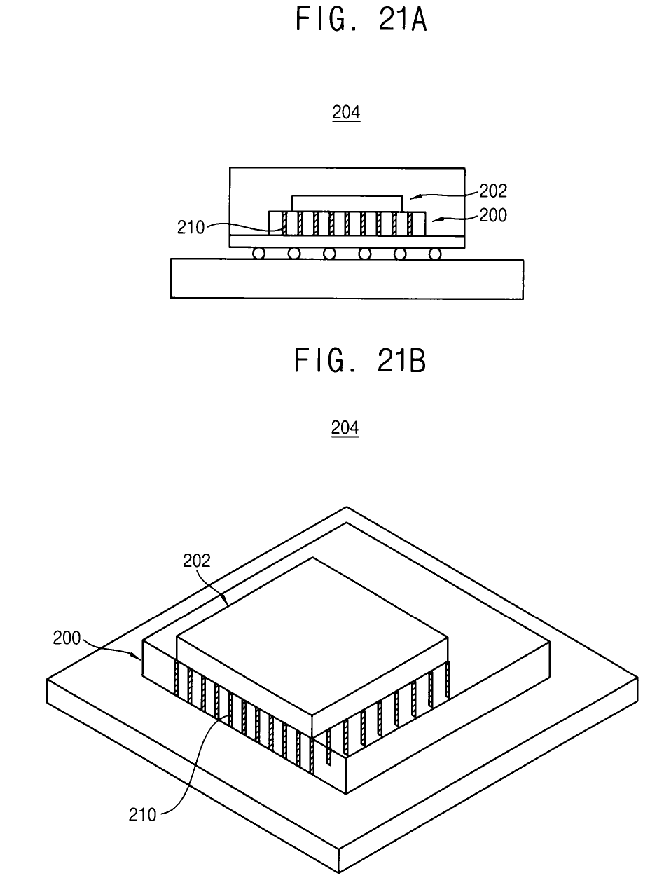

FIG. 21A is a cross-sectional view illustrating a package module including a stack chip package in accordance with principles of inventive concepts having a memory device and a logic device. FIG. 21B is a perspective view illustrating the package module in FIG. 21A.

Referring to FIGS. 21A and 21B, a three-dimensional stacked system-in-package in accordance with principles of inventive concepts 204 may include a first chip 200 having a logic device and a second chip 202 having a DRAM device. First chip 200 may be connected to second chip 202 by a through-silicon via 210.

In an exemplary embodiment in which system-in-package 204 includes through-silicon via 210, the system-in-package may have a signal path length shorter than a package with a horizontally stacked structure or a vertically stacked structure using a wire or bump, for example.

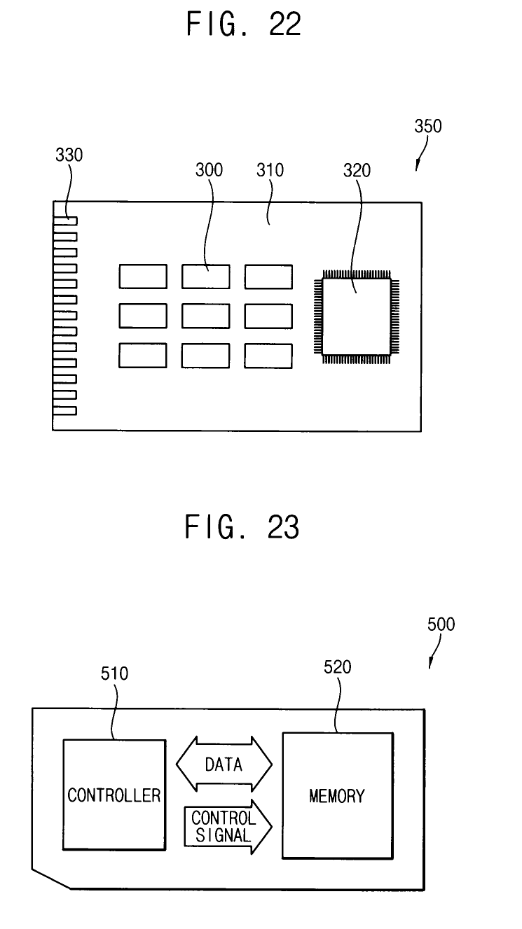

FIG. 22 is a plan view illustrating a package module including a stack chip package in accordance with an exemplary embodiment in accordance with principles of inventive concepts. Package module 350 may include a stack-chip package 300 in accordance with principles of inventive concepts. Package module 350 may include a module substrate 310 and a plurality of stack-chip packages in accordance with principles of inventive concepts mounted on module substrate 310. Package 320 may be provided in a first side portion of package module 350 and outer connection terminal 330 may be provided in a second side portion of package module 350, for example. Stack chip package 300 is not limited to such an exemplary embodiment, however, and may be applied to various package modules.

FIG. 23 is a block diagram illustrating an exemplary embodiment of a card including a stack-chip package in accordance with principles of inventive concepts. Card 500 may include a stack-chip package 300 in accordance with principles of inventive concepts. Card 500 may be a multimedia card (MMC), a secure digital card (SD), or other type of electronic card, for example. Card 500 may include a controller 510 and a memory 520. Memory 520 may be flash memory, PRAM (phase change RAM (random access memory)), or other type of memory, for example. Controller 510 may apply a control signal to memory 520 and DATA may be transferred between controller 510 and memory 520. Stack-chip packaging in accordance with principles of inventive concepts may be applied to controller 510 or memory 520, for example.

The foregoing is illustrative of exemplary embodiments in accordance with principles of inventive concepts and is not to be construed as limiting thereof. Although exemplary embodiments in accordance with principles of inventive concepts have been described, those skilled in the art will readily appreciate that many modifications are possible in exemplary embodiments without materially departing from the novel teachings and advantages of exemplary embodiments. Accordingly, all such modifications are intended to be included within the scope of exemplary embodiments in accordance with principles of inventive concepts as defined in the claims. In the claims, means-plus-function clauses are intended to cover the structures described herein as performing the recited function and not only structural equivalents but also equivalent structures. Therefore, it is to be understood that the foregoing is illustrative of various exemplary embodiments in accordance with principles of inventive concepts and is not to be construed as limited to the specific exemplary embodiments in accordance with principles of inventive concepts disclosed, and that modifications to the disclosed exemplary embodiments in accordance with principles of inventive concepts, as well as other exemplary embodiments in accordance with principles of inventive concepts, are intended to be included within the scope of the appended claims.

What is claimed is:

1. A method of inspecting a stack chip package, comprising:
preparing a first chip including a through silicon via, first pad electrodes connected to the through silicon via and probe pad electrodes connected to the through silicon via;
preparing a testing chip including second pad electrodes that are arranged to correspond with the first pad electrodes;
temporarily adhering the testing chip to the first chip such that the second pad electrodes are electrically connected to the first pad electrode respectively, to form a stack structure wherein the probe pad electrodes are exposed for probing; and
applying an electrical signal to the exposed probe pad electrodes to test the through silicon via included in the first chip.

2. The method of claim 1, further comprising removing the testing chip from the first chip when the through silicon via fails the test.

3. The method of claim 1, wherein the testing chip is a chip designed to test for the presence of a defect of the though silicon via included in the first chip.

4. The method of claim 3, wherein the testing chip comprises a wiring that connects the through silicon vias of the first chip to form a conductive connection line when the first chip and the testing chip are adhered to each other.

5. The method of claim 4, wherein inspecting the through silicon via comprises
contacting a probe needle with the probe pad electrode; and
applying the electrical signal through the probe needle to detect whether or not the electrical signal is transmitted through the through silicon vias of the conductive connection.

6. The method of claim 1, further comprising, after inspecting the through silicon via, when the through silicon via passes the test,
separating the testing chip from the first chip that has passed the test: and
tacking an operational second chip on the first chip to form a stack-chip package.

7. The method of claim 1, wherein an operational second chip is used for the testing chip.

8. The method of claim 1, wherein the testing chip is a separate chip that is diced from a wafer.

9. The method of claim 1, wherein a bump pad is formed on a surface of the first chip opposite the surface where the first pad electrode is formed, to be electrically connected to the through silicon via.

10. The method of claim 9, further comprising:
coating a first temporary adhesive layer on the surface of the first chip where the bump pad is formed; and
adhering a carrier substrate using the first temporary adhesive layer to the first chip.

11. The method of claim 1, wherein the probe pad electrode has an upper surface area greater than an upper surface area of the first pad electrode.

12. The method of claim 1, wherein when the through silicon via passes the test, the testing chip and the good first chip that are adhered to each other are used to form a stack chip package.

13. The method of claim 1, wherein the first chip is formed in a substrate before being diced into a separate chip.

14. A method of inspecting a stack chip package, comprising:
preparing a first chip including a through silicon via and first pad electrodes connected to the through silicon via;
preparing a testing chip including second pad electrodes arranged corresponding to the first pad electrodes, a second through silicon via electrically connected to the second pad electrodes and probe pad electrodes electrically connected to the second through silicon via and provided on a surface of the testing chip opposite to a surface where the second electrodes are formed;
temporarily adhering the testing chip to the first chip such that the second pad electrodes are electrically connected to the first pad electrode respectively, to form a stack structure wherein the probe pad electrodes are exposed for testing;
applying an electrical signal to the exposed probe pad electrodes to test the through silicon via included in the first chip; and
removing the testing chip from the first chip when the through silicon via fails the test.

15. The method of claim 14, wherein the testing chip is a separate chip that is diced from a wafer or a bare chip that is formed in a wafer before dicing the wafer.

16. A method of forming a stack-chip package, comprising:
adhering a test chip to a chip-under-test;
testing the chip-under-test; and
mating the chip-under-test with a second chip to form a stack-chip package if the chip-under-test passes the test.

17. The method of claim 16, wherein the testing chip is an operational chip and it is left adhered to the chip-under-test to mate to the chip-under-test if the chip under test passes the test.

18. The method of claim 16, further comprising the step of discarding the chip-under-test if it fails the test.

19. The method of claim 17, wherein the testing chip is separated from the chip-under-test if the chip-under-test fails the test and the testing chip is subsequently adhered to another chip-under-test.

20. The method of claim 19, wherein the testing chip is left adhered to the other chip-under-test to mate to the chip-under-test if the chip under test passes the test.
